(19) United States
(12) Patent Application Publication
(10) Pub. No.: US 2024/0063180 A1
(43) Pub. Date: Feb. 22, 2024

(54) IC DIE COMPOSITES WITH INORGANIC INTER-DIE FILL STRUCTURES

(71) Applicant: Intel Corporation, Santa Clara, CA (US)

(72) Inventors: Kimin Jun, Portland, OR (US); Adel Elsherbini, Chandler, AZ (US); Omkar Karhade, Chandler, AZ (US); Bhaskar Jyoti Krishnatreya, Hillsboro, OR (US); Mohammad Enamul Kabir, Portland, OR (US); Jiraporn Seangatith, Chandler, AZ (US); Tushar Talukdar, Wilsonville, OR (US); Shawna Liff, Scottsdale, AZ (US); Johanna Swan, Scottsdale, AZ (US); Feras Eid, Chandler, AZ (US)

(73) Assignee: Intel Corporation, Santa Clara, CA (US)

(21) Appl. No.: 17/891,654

(22) Filed: Aug. 19, 2022

(51) Int. Cl. H01L 25/065; H01L 25/00; H01L 21/48; H01L 23/13; H01L 23/31

(52) U.S. Cl. CPC H01L 25/0652; H01L 25/50; H01L 21/4857; H01L 23/13; H01L 23/3185; H01L 24/05

(57) ABSTRACT

Quasi-monolithic multi-die composites including a primary fill structure within a space between adjacent IC dies. A fill material layer, which may have inorganic composition, may be bonded to a host substrate and patterned to form a primary fill structure that occupies a first portion of the host substrate. IC dies may be bonded to regions of the host substrate within openings where the primary fill structure is absent to have a spatial arrangement complementary to the primary fill structure. The primary fill structure may have a thickness substantially matching that of IC dies and/or be co-planar with a surface of one or more of the IC dies. A gap fill material may then be deposited within remnants of the openings to form a secondary fill structure that occupies space between the IC dies and the primary fill structure.

### BACKGROUND

Monolithic integrated circuit (IC) fabrication has restrictions that may limit a final product's performance, and thus different versions of IC die (dis)integration are being investigated. To date however, these techniques and architectures generally suffer from certain drawbacks such as high cost, lower insertion efficiency, and increased z-height.

IC die disintegration techniques rely on advances in multi-die integration at the package level. In electronics manufacturing, IC packaging is a stage of semiconductor device fabrication in which an IC that has been monolithically fabricated on a chip (or die) comprising a semiconducting material is assembled into a “package” that can protect the IC chip from physical damage and support electrical contacts that connect the IC to a scaled host component, such as an organic package substrate, or a printed circuit board. Multiple chips can be similarly assembled together, for example, into a multi-chip package (MCP).

Such multi-chip architectures may advantageously combine IC chips from heterogeneous silicon processes and/or combine small dis-aggregated chips from identical silicon processes. However, there are many challenges with integrating multiple IC die into such a chip-scale unit. For example, inter-die fill material, such as an epoxy based mold can introduce high stress that can cause a mechanical reliability problem as the thickness of multi-die composite structures is reduced. In alternative inter-die fill techniques where inter-die spaces are filled with inorganic material in an effort to mitigate stress-induced failure, the gap-fill deposition techniques (e.g., PECVD) can be prohibitively slow and/or expensive.

Accordingly, alternative multi-die quasi-monolithic chip architectures, and techniques associated with those architectures, may therefore be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming a multi-die composite structure including a primary fill structure and a secondary fill structure, in accordance with some embodiments;

FIG. 2A is cross-sectional view of a donor substrate including a fill material layer, in accordance with some embodiments;

FIG. 2B is a cross-sectional view of a host substrate including metallization features, in accordance with some embodiments;

FIG. 2C is a cross-sectional view illustrating transfer of a fill material layer to a host substrate, in accordance with some embodiments;

FIG. 3A is a cross-sectional view of through vias formed within a transferred fill material layer, in accordance with some embodiments;

FIG. 3B is a cross-sectional view of primary fill structure patterned from a fill material layer, in accordance with some embodiments;

FIG. 3C is a plan view of the primary fill structure illustrated in FIG. 3B, in accordance with some embodiments;

FIG. 4A is a cross-sectional view of IC dies placed within openings of a primary fill structure, in accordance with some embodiments;

FIG. 4B is a cross-sectional view of IC dies bonded into a composite IC die structure, in accordance with some embodiments;

FIG. 4C is a plan view of the IC die package illustrated in FIG. 4B, in accordance with some embodiments;

FIG. 5A is a cross-sectional view of a secondary fill structure formed within remnants of a space between adjacent IC dies, in accordance with some embodiments;

FIG. 5B is a cross-sectional view of a secondary fill structure planarized with adjacent IC dies and a primary fill structure, in accordance with some embodiments;

FIG. 5C is a cross-sectional view of a composite IC die structure after stacking an additional IC die and the formation of another primary fill structure, in accordance with some embodiments;

FIG. 6 illustrates a system including the composite IC dies structure illustrated in FIG. 5C attached to a host component with FLI features, in accordance with some embodiments;

FIG. 7 illustrates a mobile computing platform and a data server machine employing an composite IC die structure including one or more primary fill structures, in accordance with some embodiments; and

FIG. 8 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Multi-die composites including IC die directly bonded to a host substrate within openings of a primary fill structure are described herein. For such “composite” die structures, which may also be referred to as “quasi-monolithic chip” structures, at least some of the die are directly bonded to the host substrate rather than being interconnected with a joining material, such as solder. The IC die composites described further include at least one primary fill structure. In contrast to a passive or dummy IC die, a primary fill structure has openings to accommodate bonding of the IC die. Accordingly, the primary fill structure may surround two or more side edges of one or more of the IC dies.

Originating from a preformed material layer that may be transferred to the host substrate, the chemical composition of a primary fill structure may be selected to be a good electrical insulator. The primary fill structure may also have a bulk thermal conductivity that exceeds typical organic and inorganic dielectric materials. The primary fill structure may also have mechanical properties that are well-matched to those of (active) IC die. For example, a primary fill structure may have a bulk coefficient of thermal expansion (CTE) that is substantially the same as that of one or more of the IC dies or host substrate. The primary fill structure may therefore mechanically and thermally interconnect IC die of a composite structure. As further described below, a primary fill structure may comprise through vias or other metallization structures, which may facilitate electrical interconnection of IC die stacked within an IC die composite structure.

Bonding techniques may be enlisted both in the transfer of a fill material layer and for the integration of IC die. Where both the metal features and the host substrate and IC die are fused, the resultant composite or quasi-monolithic structure comprises a hybrid bonded interface of both metallurgically interdiffused metals and chemically bonded insulators. Prior to IC die bonding, each (active) IC die may be fabricated in a monolithic process separate from each other. As such, each IC die may be fabricated with the same or different wafer fab technologies. Each IC die may be fabricated to support face-to-face, face-to-back, or back-to-back bonding with another IC die.

Prior to bonding of a fill material layer, the fill material layer may be fabricated with techniques that efficiently achieve a layer thickness comparable to that of the IC die. After forming the primary fill structure and bonding the IC die where the primary fill structure is absent, a secondary fill structure may be formed to backfill any remnant space between the primary fill structure and the IC die. Accordingly, a secondary fill material need only be deposited to a thickness based on the remnant space that can be as small a practical for a given bonding technology.

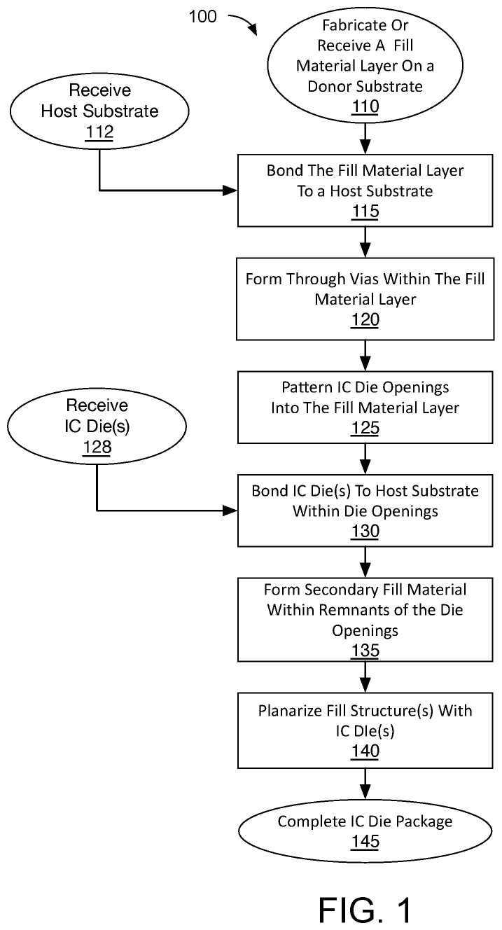

A number of different assembly and/or fabrication methods may be practiced to form an IC die composite having one or more of the features or attributes described herein. FIG. 1 illustrates a flow diagram of methods 100 for forming an IC die composite including a primary fill structure and a secondary fill structure, in accordance with some embodiments.

Methods 100 begin at input 110, where a fill material layer is fabricated, or received as a preform that has been fabricated upstream of methods 100. The fill material layer is advantageously an inorganic material, rather than an organic material. The fill material layer may be fabricated monolithically upon a donor substrate, such as a glass or silicon (e.g., monocrystalline) starting wafer, for example. Alternatively, the fill material layer may be the donor substrate itself. Any substrate fabrication process may be employed to fabricate a donor substrate that includes a suitable fill material layer.

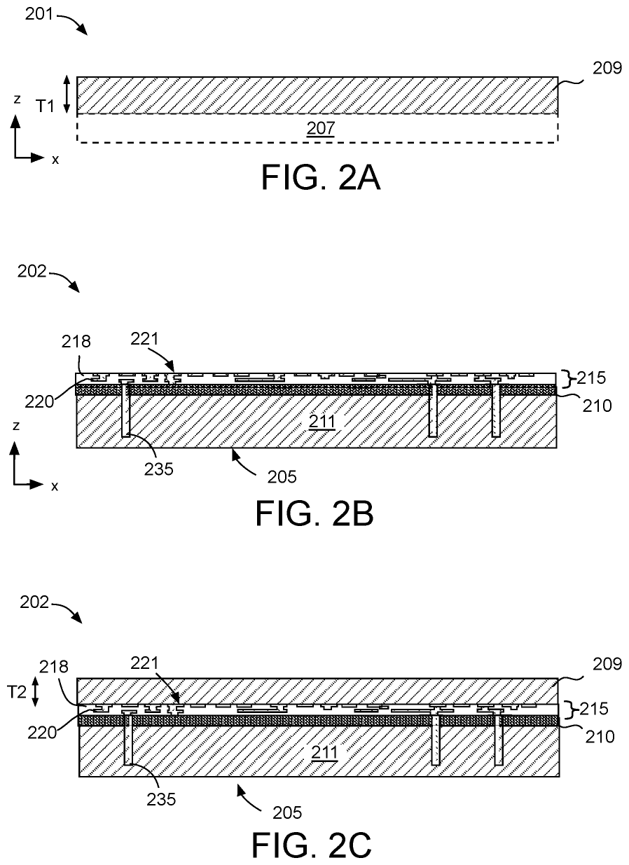

In the example illustrated in FIG. 2A, a donor substrate 201 is a bulk semiconductor wafer, which may be predominantly monocrystalline silicon, silicon carbide, germanium, sapphire, or the like. For such embodiments, some portion of the donor substrate thickness T1 is to serve as a fill material layer 209. In other embodiments, donor substrate 201 is semiconductor-on-insulator (SOI) wafer including a fill material layer 209 of predominantly monocrystalline silicon, silicon carbide, or the like, on a handle wafer 207. In other embodiments, donor substrate 201 includes a fill material layer 209 of predominantly silica, or an alternative glass that can provide similarly low electrical coupling between IC die of an IC die composite. In other embodiments, donor substrate 201 comprises another inorganic dielectric material, such as, but not limited to, SiN or SiON, etc. that is to become fill material layer 209. For embodiments where very low stress is required, fill material layer 209 may be a spin-on-dielectric. In still other embodiments where large thermal conductivity is required, donor substrate 201 may comprise a graphite layer or a predominantly metal layer that is to serve as a fill material layer 209.

Hence, the composition of donor substrate 201 may be selected to provide a fill material layer 209 that is a good electrical insulator, a semiconductor, or a good electrical conductor. The composition of donor substrate 201 may be further selected to provide a fill material layer 209 that has a bulk thermal conductivity that exceeds typical organic and/or inorganic dielectric materials. The composition of donor substrate 201 may be further selected to provide a fill material layer 209 with good mechanical properties, such as CTE, that are well-matched to those of a host substrate and/or active IC die that are to be within an IC die composite structure. Regardless of composition and microstructure, the thickness T1 of fill material layer 209 is advantageously at least equal to a thickness of IC die that are to be adjacent to fill material layer 209. In some embodiments, thickness T1 is at least 20 μm and may be in the range of 20-200 μm, or more.

Returning to FIG. 1, methods 100 continue with the fabrication of a host substrate or the receipt of a host substrate that has been fabricated upstream of methods 100. The host substrate may be any IC die, interposer, or package substrate suitable for a multi-chip composite architecture. In the example illustrated in FIG. 2B, a host substrate 202 has a back side 205 comprising a substrate material 211. In some examples, substrate material 211 is silicon. In other examples, substrate material 211 is an alternative crystalline material, such as, but not limited to, germanium, SiₓGe₁₋ₓ, GeₓSn₁₋ₓ or silicon carbide. In still other examples, substrate material 211 is a glass (e.g., silica), which can have flatness approximately equal to that of crystalline substrates, but at a lower cost.

In some embodiments, host substrate 202 is an “active” IC die and includes a device layer 210 fabricated in, or on, substrate material 211. Device layer 210 may be homogenous with substrate material 211, or not (e.g., a transferred substrate). Device layer 210 (and a homogeneous IC die substrate material 211) may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, IC device layer 210 is a Group III-V material comprising a Group III majority constituent and a Group IV majority constituent (e.g., InGaAs, GaAs, GaSb, InGaSb). IC die device layer 210 may have a thickness of 50-1000 nm, for example. IC die device layer 210 need not be a continuous layer of semiconductor material, but rather may include active regions of semiconductor material surrounded by field regions of isolation dielectric.

In some embodiments, the active devices within device layer 210 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die device layer 210 may include active devices other than FETs. For example, IC die device layer 210 may include electronic memory structures, such as magnetic tunnel junctions (MTJs), capacitors, or the like.

In alternative embodiments, host substrate 202 is “passive” and lacks device layer 210. Regardless of whether host substrate 202 is active or passive, host substrate 202 may include passive devices such as resistors, capacitors, or inductors (not depicted).

Host substrate 202 has a front side 221 that comprises one or more metallization levels 215. In exemplary embodiments, metallization levels 215 include metallization features 220 embedded within an insulator 218. While metallization features 220 may have any composition(s) of sufficient electrical conductivity, in exemplary embodiments, metallization features 220 are predominantly copper (Cu). In other examples, metallization features 220 are predominantly other than Cu, such as, but not limited to predominantly Ru, or predominantly W. An uppermost one of metallization layers 215 includes “bondable” metallization features 220 that have an associated feature pitch suitable for directly bonding to complementary conductive features of an IC die. This feature pitch may range from 100 nm to several microns, for example.

Insulator 218 may have any composition(s) suitable as an electrical insulator. In exemplary embodiments, insulator 218 is an inorganic interlayer dielectric (ILD) material having any material composition known to be suitable as an insulator of monolithic integrated circuitry, such as, but not limited to, silicon dioxide, silicon nitride, silicon oxynitride, or a low-k material having a relative permittivity below 3.5. In some embodiments, ILD materials vary in composition with a lower ILD material layer 218 comprising a low-k dielectric material and an uppermost ILD material layer 218 comprising a conventional dielectric material (e.g., having a dielectric constant of approximately 3.5, or more). Confining low-k dielectric materials distal from a bond interface in this manner may advantageously improve bond strength and/or quality. In other embodiments where low-k dielectric material can form a strong bond interface, all ILD material layers 218 may all be a low-k material (e.g., having a relative permittivity of 1.5-3.0).

Returning to FIG. 1, methods 100 continue at block 115 where the fill material layer is bonded to a working (e.g., top) surface of the host substrate. Any bonding process suitable for the composition of the fill material layer and the working surface of the host substrate may be practiced at block 115. In some examples, block 115 entails compression and/or thermal compression bonding. After bonding, a portion of a donor substrate may be separated from the fill material layer, in which case a fill material layer is transferred from the donor substrate to the host substrate. Alternatively, an entirety of the donor substrate may remain bonded to the host substrate, in which case the donor substrate is the fill material layer. In either implementation, the fill material layer may be thinned after bonding.

In the example illustrated in FIG. 2C, host substrate 202 comprises fill material layer 209, which may be, for example, bonded to one or more of insulator 218 and metallization features 220. Following a planarization, fill material layer 209 may have any remaining thickness T2. In exemplary embodiments, T2 is less than T1, but at least equal to a thickness of IC die that are to be adjacent to fill material layer 209. In some embodiments, thickness T2 is at least 20 μm and may be in the range of 20-200 μm, or more.

Returning to FIG. 1, methods 100 continue at block 120 where metallization features, such as through vias, are fabricated into the fill material layer. Block 120 is optional and may be excluded from the practice of methods 100. Block 120 may also be practiced prior to block 115 (e.g., upstream of methods 100) so that the fill material layer bonded at block 115 includes such metallization features. However, in exemplary embodiments the optional fabrication of metallization features at block 120 is practiced after bonding of the fill material layer so that the bonding process at block 115 need not require precise alignment between the metallization features and the host substrate. The fabrication of metallization features within the fill material layer may be practiced before bonding of IC die(s), as illustrated in FIG. 1. Alternatively, the fabrication of metallization features within the fill material layer may also be practiced after bonding of IC die(s), for example after block 140 in FIG. 1. Block 120 may include any processes known to be suitable to form metallization features, and more particularly any processes known to be suitable to form conductive vias extending through the thickness of the fill material layer. The fabrication of through vias may, for example, comprise a patterned etch process that forms via openings and a metal deposition process that fills the via openings with a metal.

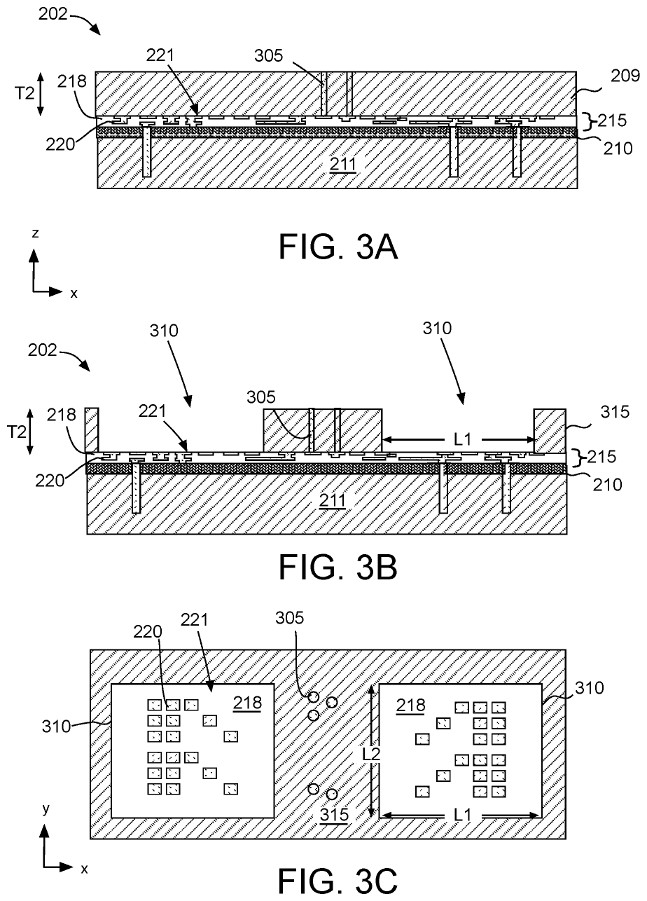

FIG. 3A further illustrates an example where through vias 305 extend through thickness T2 of fill material 209 and contact metallization features 220. Any number of through vias 305 may be fabricated according to any suitable technique. For some embodiments where fill material layer 209 comprises predominantly silicon, openings for through vias 305 may be fabricated with a Bosch-type via etch process, for example. In other embodiments, openings for through vias 305 may be fabricated with a laser drill/ablation process. Through vias 305 may comprise one or more conductive materials, such as, but not limited to, Cu that have been deposited within the via openings.

Methods 100 (FIG. 1) continue at block 125 where one or more openings, each of an area sufficient to accommodate one or more IC dies are patterned into the fill material layer. In exemplary embodiments, a patterned etch process is performed at block 125. The patterned etch process may be similar to an etch process performed at block 120, for example. However, since the openings formed at block 125 are much larger than via openings (e.g., millimeters on a side), the material removal technique is not as constrained as for the fabrication of via openings. In some examples, a wet etch process or laser drilling process may be practiced at block 125.

In the example further illustrated in FIG. 3B, IC die openings 310 have been formed through thickness T2, rendering the fill material layer 209 a primary fill structure 315 that is to surround at least two sidewall edges of one or more IC dies of a composite structure. Primary fill structure 315 is further illustrated in the plan view of FIG. 3C. As shown in FIGS. 3B and 3C, openings 310 have orthogonal lateral dimensions L1 and L2, which are predetermined based on dimensions of an IC die that is to be positioned within openings 310. In exemplary embodiments, at least one of lateral dimensions L1 or L2 is on the order of millimeters in length. Host substrate front side 221 is exposed within each of the openings 310.

Returning to FIG. 1, methods 100 continue with the receipt of one or more IC dies at input 128. Each IC die received may have been fabricated upstream of methods 100 according to any technique known to be suitable. The IC dies received at input 128 may be fully functional ASICs, or may be chiplets or tiles that have a more limited functionality supplementing the function of one or more other IC dies. A chiplet or tile may, for example, be any of a wireless radio circuit, microprocessor core, electronic memory circuit, floating point gate array (FPGA), power management and/or power supply circuit, or include a MEMS device.

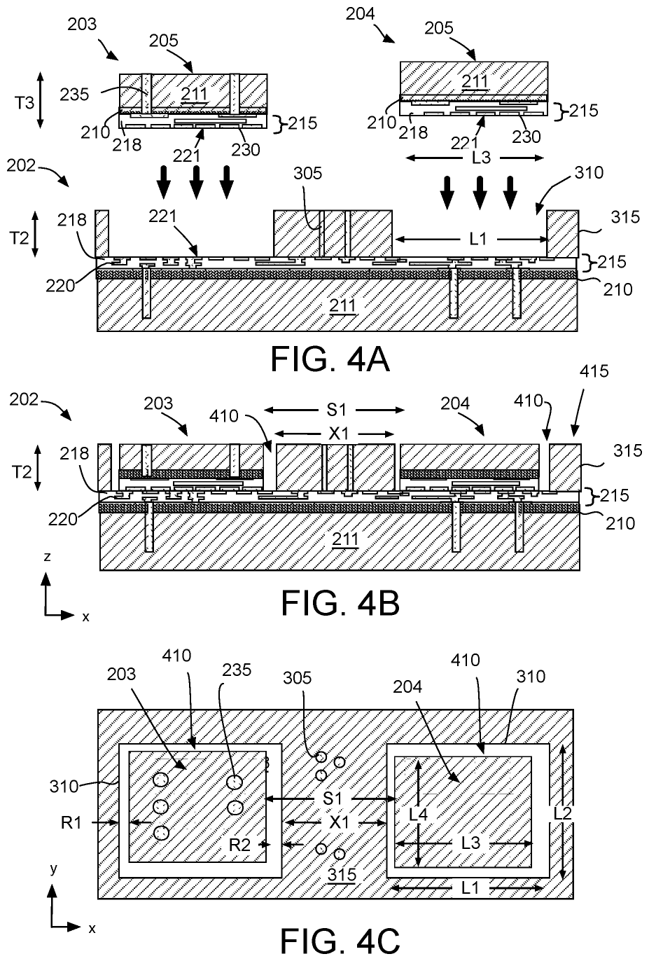

In the example further illustrated in FIG. 4A, IC die 203 and IC die 204 are being aligned for bonding within openings 310 of primary fill structure 315. IC dies 203, 204 may be “face-to-face” bonded where features on a front-side of IC dies 203, 204 are bonded to features on a front-side of host substrate 202. In alternative embodiments, IC dies 203, 204 may be “face-to-back” or “back-to-face” bonded to host substrate 202.

Each of IC die 203 and IC die 204 may have any sidewall edge length L3 and any circuit functionality. In some other examples, IC dies 203 or 204 include one or more banks of active repeater circuitry to improve multi-chip interconnects (e.g., network-on-chip architectures). A repeater bank may, for example, support 2000+ signals within an IC die area of 0.4 mm². In other examples, IC die 203 or IC die 204 includes clock generator circuitry or temperature sensing circuitry. In other examples, IC die 203 or IC die 204 includes one or more ESD banks. In other examples, IC die 203 or IC die 204 includes logic circuitry that, along with other IC die implements 3D logic circuitry (e.g., mesh network-on-chip architectures). In still other examples, at least one of IC die 203 or IC die 204 includes microprocessor core circuitry, for example comprising one or more shift registers.

As shown in FIG. 4A, IC die 203 and IC die 204 each include a device layer 210 over substrate material 211, and metallization levels 215 on the front side 221. Device layer 210, substrate material 211 and metallization levels 215 may have any of the properties described above for a host substrate 202 that is also an IC die, for example. In the illustrated arrangement, front side 221 of IC dies 203, 204 are to bond with front side 221 of host substrate 202 in a face-to-face configuration. In the illustrated example, IC die 203 further includes TSVs 235 extending through IC die substrate material 211.

The arrows in FIG. 4A represent positional alignment of bondable metal features on host substrate 202 to corresponding metal features on IC dies 203, 204. The feature pitch at the bond interface accommodates alignment imprecision. The feature pitch of the metal features on IC dies 203, 204 and host substrate 202 may therefore be predetermined based on alignment capabilities of a particular bonder.

FIG. 4B illustrates a cross-sectional view of an IC die composite structure following hybrid bonding of IC dies 203, 204 to host substrate 202 so that the IC dies 203, 204 are adjacent to each other with a space S between their nearest edge sidewalls. Hybrid bonding surfaces of dies 203-204 are substantially co-planar. As shown, primary fill structure thickness T2 (e.g., 20-200 μm) is substantially equal to thickness T3 of IC die 203 and/or IC die 204. Die surface 205 for each of IC dies 203, 204 is therefore substantially co-planar with surface 415 of primary fill structure 315.

Bonding of the IC die may be according to any alignment and bonding process suitable for the IC die and host substrate. For example, an IC die of a relative large sidewall edge length L2 may be handled and aligned to a target location on the host substrate according to pick-and-place die assembly methods and systems. Many such methods and systems can handle an object as thin as 100 μm and with sidewall edge length L3 ranging from tens of millimeters down to −200 μm. Die attachment may also comprise one or more micro device assembly techniques including so-called transfer printing methods, which are capable of handling an object as thin as 1 μm and having lateral dimensions in the tens of micrometers. Such micro device assembly techniques may rely on a MEMS microtool that includes hundreds or even thousands of die attachment points. Micro device assembly methods and systems suitable for inorganic LED (iLED) technology, for example, may be employed to transfer a plurality of IC chiplets concurrently from a source IC die substrate to multiple host substrates arrayed within a wafer or panel.

IC dies 203, 204 may be aligned to a target location on host substrate 202 with any high-resolution alignment tool, for example of the type found on a wafer-level or chip-level bonding tool commercially available through various industry suppliers. Alignment capability continues to advance, having improved from +/−5 μm to +/−0.2 μm over recent years. Once adequately aligned, and direct bonding technique(s) suitable for the IC die and host substrate may be practiced. Direct bonding of host substrate 202 to IC dies 203, 204 may be metal-to-metal, for example, during which metallization features sinter. In some embodiments, a hybrid bond is formed both between metallization features (e.g., via metal interdiffusion) and between dielectric materials (e.g., via Si—O—Si condensation bonds). Thermo-compression bonding may be at low temperature (e.g., below melting temperature of the interconnects, and more specifically below 100° C.). Direct bonding at room temperature (i.e., compression only) is also possible. Prior to bonding, any of host substrate 202 or IC dies 203, 204 may be pre-processed, for example with a plasma clean, to activate their surfaces for the bonding. Post bonding, selective heating may be performed to make permanent the bond (e.g., by converting a van der waals bond into a sintered Cu—Cu bond through interdiffusion). For selective heating, a laser may be employed to limit heating to a specific one IC die 203, 204.

In some embodiments, lateral (e.g., x-axis) misalignment or misregistration between conductive features of host substrate 202 and IC dies 203, 204 is less than 0.2 μm. For example, lateral misalignment between one conductive feature (e.g., a line or trace) and another conductive feature (e.g., a via) within a monolithic IC die may be at least an order of magnitude smaller than the lateral misalignment between bonded conductive features. The lateral dimensions of metallization features at the bond interface are sufficiently large to accommodate such lateral offset. Where multiple IC die 203 and IC die 204 are bonded individually to host substrate 202, the magnitude of the lateral offset may vary between the IC die.

As shown in the cross-sectional view of FIG. 4B and the plan view of FIG. 4C, most of the space S1 between two adjacent IC die 203 and 204 is occupied by primary fill structure 315. However, because of clearance needed for alignment of IC die to the host substrate, primary fill structure 315 occupies some fraction X1 of space S1. A remainder of space S1 comprises channels 410, which may surround a perimeter of IC die 203 and/or 204 for embodiments where primary fill structure 315 completely surrounds the perimeter of IC die 203 and/or 204. The remnant widths R1 and/or R2 may vary depending on die alignment clearance, for example from 5-50 μm. As a result of any misalignment of IC die 203 and/or 204, channels 410 may have lateral remnant widths R1 and R2 that differ between two opposite sidewall edges of an IC die within one lateral dimension (e.g., x or y axis). A magnitude of the difference between remnant widths R1 and R2 may significantly exceed 50% of the smaller of R1 and R2.

Returning to FIG. 1, methods 100 continue with further processing of the IC die composite. In exemplary embodiments, at block 135 a secondary fill structure is formed between sidewall edges of the IC die and the primary fill structure. This secondary fill structure may, for example, provide a moisture seal around the bond interface of each IC die since the primary fill structure does not occupy all space between adjacent IC die. Accordingly, the secondary fill structure can merely be a gap filler of much less thickness than that of the primary fill structure.

In some embodiments, a secondary fill material layer is conformally deposited over the IC die and primary fill structure, for example with chemical vapor deposition (CVD) or plasma enhanced CVD (PECVD) at block 130. In other embodiments, the second fill material is deposited over the IC die and primary fill structure with a spin-on or molding process, or a lamination. As the secondary fill material layer is to hermetically seal the bond interface, is composition may vary from that of the primary fill structure. In exemplary embodiments, the secondary fill material layer is an electrical insulator. However, in alternative embodiments, the second fill material layer may instead comprise an electrical conductor (e.g., a metal or metallic compound), or a semiconductor (e.g., amorphous silicon).

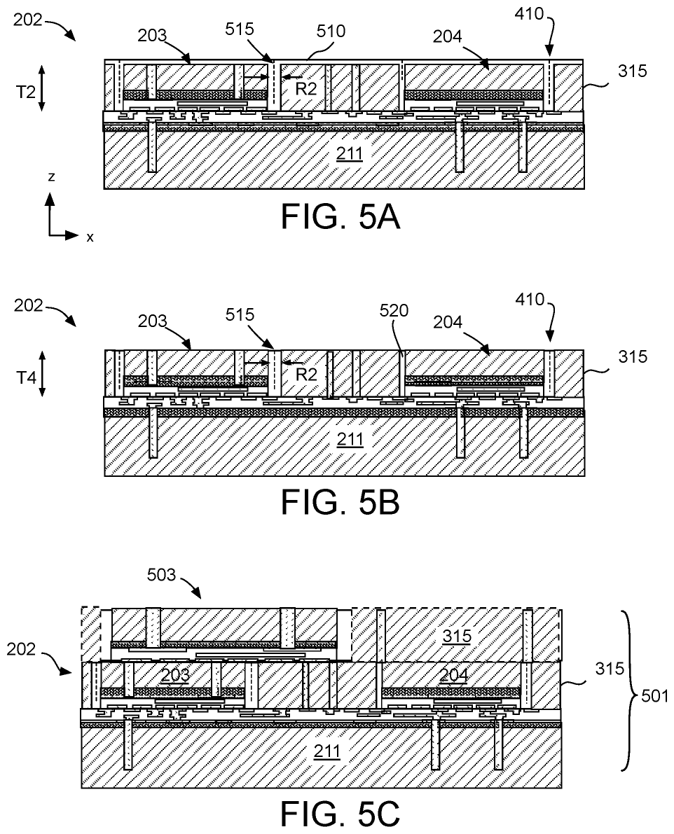

FIG. 5A illustrates a cross-sectional view of a substantially conformal secondary fill material layer 510, in accordance with some embodiments. Because of the conformality of gap filling deposition process, secondary fill material layer 510 is in contact with a sidewall of primary fill structure 315 and in contact with a sidewall of each of IC dies 203, 204. As a conformal gap filler, secondary fill material layer 510 may have a seam or interface 515 located substantially in the middle of channels 410 (e.g., at ½R1 and ½ R2, etc.). Although composition may vary with implementation, in exemplary embodiments secondary fill material layer 510 is an inorganic dielectric material. In some embodiments where primary fill material 315 is predominantly silicon, silicon carbide or a metal, secondary fill material layer 510 may comprise more nitrogen and/or oxygen than primary fill material 315. In one example, secondary fill material layer 510 is silicon nitride. In other embodiments, secondary fill material layer 510 an organic material, such as an epoxy with one or more fillers. In still other embodiments, secondary fill material layer 510 is amorphous silicon, amorphous carbon, a metal (e.g., Ti or Cu), or a metallic compound (e.g., TiN, Al₂O₃, or HfO₂)

In contrast to primary fill structure 315, which was not deposited upon IC dies 203, 204, secondary fill material layer 510 does contact a back or top side of IC dies 203, 204. Secondary fill material layer 510 may also substantially fill channels 410 although in some alternative embodiments it may only bridge channels 410.

Returning to FIG. 1, methods 100 continue at block 140 where the secondary fill material is planarized with one or more of the primary fill structure or the IC die. Such planarization may form a secondary fill structure occupying only a channel between sidewall edges of the IC die and primary fill structure. In the example further illustrated in FIG. 5B, a grind, polish, or other planarization process has removed any overburden of secondary fill material layer 510 to arrive at a secondary fill structure 520 that remains only within channels 410 between IC die 203, 204 and primary fill structure 315. Following planarization, primary fill structure 415 may have a final thickness T4 that is substantially equal to that of IC die 203 and/or IC die 204. Secondary fill structure 520 may also have the final thickness T4.

Returning to FIG. 1, methods 100 end at output 145 where the IC die composite structure is completed. In some embodiments, completion of the package entails stacking another level of IC die upon one or more of the IC dies already in the quasi-monolithic structure. In some specific embodiments, completion of the composite comprises one or more additional iterations of blocks 115-140 where another primary fill structure is bonded between another level of adjacent IC dies. For example, as further illustrated in FIG. 5C, a completed IC die package 501 includes an upper-level IC die 503 bonded to one or more lower-level IC dies 203, 204 and/or lower primary fill structure 315. An upper-level primary fill structure 315 may be adjacent to two or more sidewall edges of upper-level IC die 503 substantially as describe elsewhere herein for IC die 203, 204.

Following completion of a composite IC die structure, first level interconnects (FLI) may be formed on exposed surfaces of conductive features of the IC die package in preparation for a next level of assembly. In exemplary embodiments, solder features are formed as the FLI. The IC die composite may be singulated according to any techniques known to be suitable for stacked die.

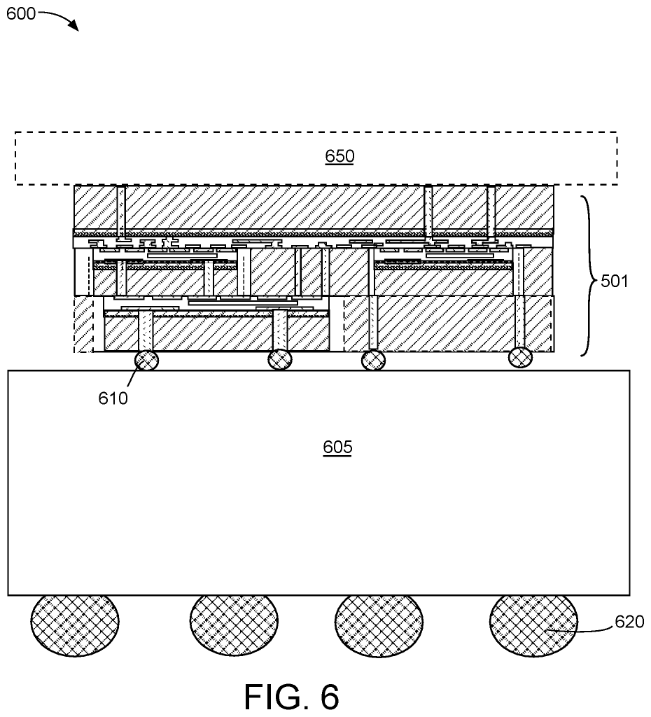

FIG. 6 illustrates a system including IC die composite 501 attached to a host component 605 by reflowing FLI features 610. In exemplary embodiments, FLI features 610 are solder (e.g., SAC) microbumps although other interconnect features are also possible. In some embodiments, host component 605 is predominantly silicon. Host component 605 may also comprise one or more alternative materials known to be suitable as interposers or package substrates (e.g., an epoxy preform, cored or coreless laminate board, etc.). Host component 605 may include one or more metallized redistribution levels (not depicted) embedded within a dielectric material. Host component 605 may also include one or more IC die embedded therein. For example, an IC interconnect bridge (not depicted) may be embedded within metallized redistribution levels of host component 605, for example to electrically couple IC die composite 501 to another IC, such as a memory IC die (not depicted) or another composite IC die structure.

As further shown in FIG. 6, host component 605 (e.g., a package substrate) may be further coupled to another host, such as a mother board or other PCB, by second level interconnects (SLI) 620. SLI 620 may comprise any solder (ball, bump, etc.) suitable for a given host board architecture (e.g., surface mount FR4, etc.). As illustrated in dashed line, one or more heat spreaders and/or heat sinks 650 may be further coupled to backside of IC die composite structure 501, which may be advantageous, for example, where IC die composite 501 comprises one or more CPU cores or other IC die of similar power density.

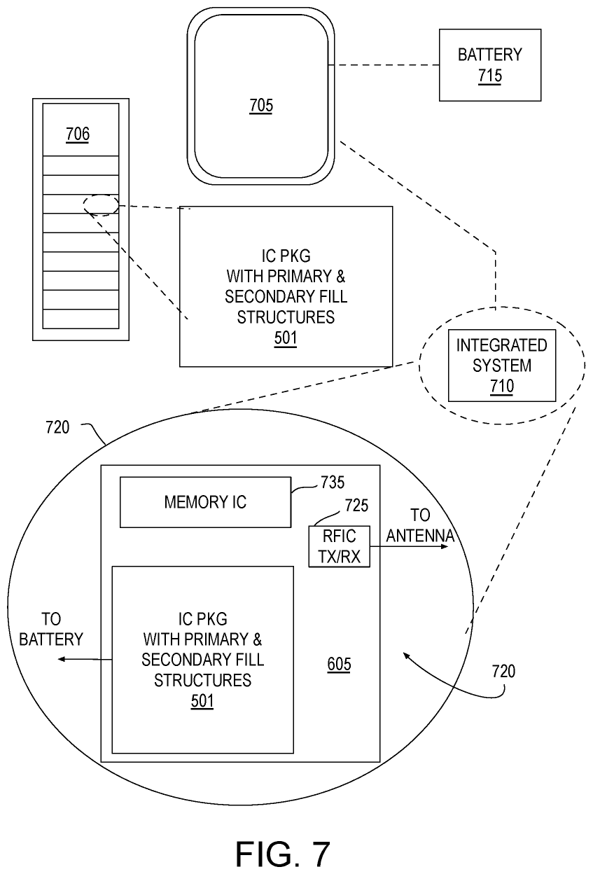

FIG. 7 illustrates a mobile computing platform 705 and a data server machine 706 employing a composite IC die structure including a primary fill structure and a secondary fill structure, for example as described elsewhere herein. Server machine 706 may be any commercial server, for example including any number of high-performance computing platforms disposed within a rack and networked together for electronic data processing, which in the exemplary embodiment includes IC die composite 501 that includes a primary fill structure and a secondary fill structure, for example as described elsewhere herein. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), an integrated system 710, and a battery 715.

As illustrated in the expanded view 720, IC die composite 501 is further coupled to host component 605, along with one or more memory IC 735. One or more of a power management integrated circuit (PMIC) 730 or RF (wireless) integrated circuit (RFIC) 725 including a wideband RF (wireless) transmitter and/or receiver may be further coupled to host component 605. PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

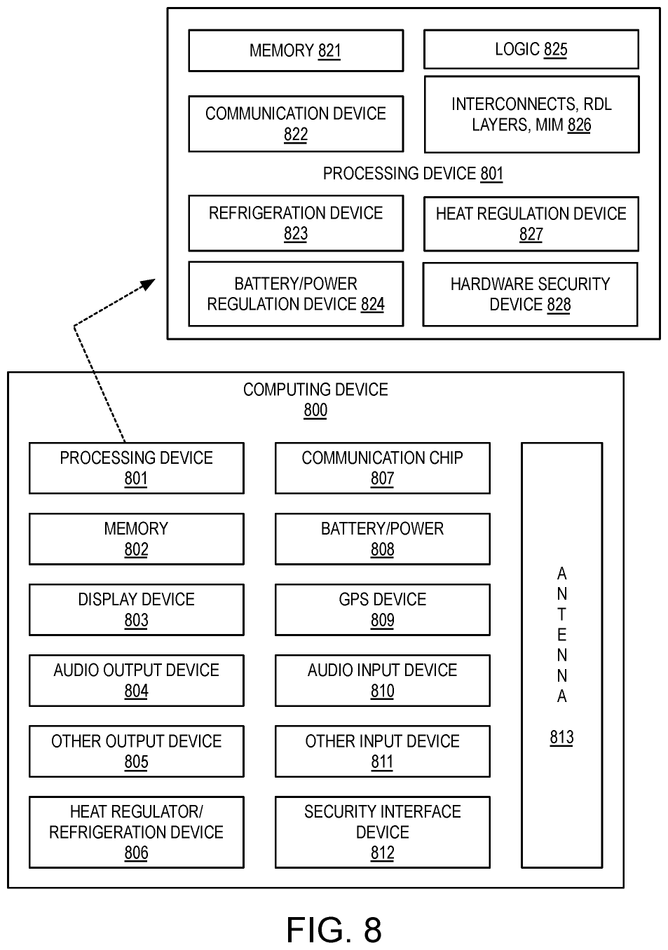

FIG. 8 is a block diagram of a cryogenically cooled computing device 800 in accordance with some embodiments. For example, one or more components of computing device 800 may include any of the devices or structures discussed elsewhere herein. A number of components are illustrated in FIG. 8 as included in computing device 800, but any one or more of these components may be omitted or duplicated, as suitable for the application. In some embodiments, some or all of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled.

Computing device 800 may include a processing device 801 (e.g., one or more processing devices). As used herein, the term processing device or processor indicates a device that processes electronic data from registers and/or memory to transform that electronic data into other electronic data that may be stored in registers and/or memory. Processing device 801 may include a memory 821, a communication device 822, a refrigeration/active cooling device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 801 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 821 includes memory that shares a die with processing device 802. This memory may be used as cache memory and may include embedded dynamic random-access memory (eDRAM) or spin transfer torque magnetic random-access memory (STT-M RAM).

Computing device 800 may include a heat regulation/refrigeration device 806. Heat regulation/refrigeration device 806 may maintain processing device 802 (and/or other components of computing device 800) at a predetermined low temperature during operation. This predetermined low temperature may be any temperature discussed elsewhere herein.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a global positioning system (GPS) device 809 (or corresponding interface circuitry, as discussed above). GPS device 809 may be in communication with a satellite-based system and may receive a location of computing device 800, as known in the art.

Computing device 800 may include another output device 805 (or corresponding interface circuitry, as discussed above). Examples include an audio codec, a video codec, a printer, a wired or wireless transmitter for providing information to other devices, or an additional storage device.

Computing device 800 may include another input device 811 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, managing access lists, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

In first examples, an integrated circuit (IC) device comprises a first IC die comprising a first surface bonded to a first region of a substrate, and a second IC die adjacent to the first IC die and comprising a first surface bonded to a second region of the substrate. The device further comprises a primary fill structure having an inorganic composition. The primary fill structure occupies a majority of a space between the first and second IC die and adjacent to two or more sidewall edges of at least the first IC die, but not over a second surface, opposite the first surface, of either of the first or second IC dies. The device comprises a secondary fill structure within a first remnant of the space between the primary fill structure and the two or more sidewall edges of the first IC die, and within a second remnant of the space between the primary fill structure and the second IC die.

In second examples, for any of the first examples the secondary fill structure comprises a seam approximately in the middle of each of the first and second remnants of the space.

In third examples, for any of the first through second examples the secondary fill structure is in contact with a sidewall of the primary fill structure and in contact with a sidewall of each of the first and second IC dies.

In fourth examples, for any of the first through third examples the primary fill structure has a thickness substantially equal to that of the first IC die and the majority of the space occupied by the primary fill structure is at least 500 μm wide. At least one of first or second remnants of the space adjacent to the primary fill structure is less than 40 μm wide.

In fifth examples, for any of the fourth examples a width of the first and second remnants of the space are unequal by at least 50% of the smaller of the first or second remnants.

In sixth examples, for any of the first through fifth examples the primary fill structure surrounds a perimeter of at least the first IC die, the secondary fill structure is within a channel surrounding the perimeter of the first IC die, and the secondary fill structure is substantially co-planar with the first IC die.

In seventh examples, for any of the sixth examples the primary fill structure surrounds a perimeter of the second IC die, the secondary fill structure is within a second channel surrounding the perimeter of the second IC die, the secondary fill structure is substantially co-planar with the second IC die, and the primary fill structure is contiguous between the first and second channels.

In eighth examples, for any of the sixth through seventh examples the channel has a different width between the two or more sidewall edges of the first IC die and two or more corresponding sidewall edges of the primary fill structure that face the sidewall edges of the first IC die.

In ninth examples, for any of the first through eighth examples a top surface of the primary fill structure is substantially planar with the second surface of at least one of the first IC die or second IC die.

In tenth examples, for any of the ninth examples the top surface of the primary fill structure is substantially planar with a top surface of the secondary fill structure.

In eleventh examples, for any of the first through tenth examples the primary fill structure has a significantly higher silicon or metal content than the secondary fill structure.

In twelfth examples, for any of first through eleventh examples the primary fill structure comprises predominantly silicon, predominantly silicon and carbon, or predominantly a metal.

In thirteenth examples, for any of the first through twelfth examples the secondary fill structure comprises a greater amount of one or more of a metal, nitrogen, or oxygen than the primary fill structure.

In fourteenth examples, for any of the first through thirteenth examples the first and second IC dies are directly bonded to the substrate, and wherein the primary fill structure is directly bonded to the substrate.

In fifteenth examples, for any of the first through fourteenth examples the device further comprises one or more through vias embedded within the primary fill structure and directly bonded to interconnect features of the substrate, and wherein a top surface of the through vias are substantially co-planar with the second surface of the primary fill structure.

In sixteenth examples, a system comprises a host component, and a composite integrated circuit (IC) device attached to the host component. The composite IC device comprises a host substrate; a first IC die comprising a first surface bonded to a first region of a substrate; a second IC die adjacent to the first IC die and comprising a first surface bonded to a second region of the substrate; a primary fill structure having an inorganic composition. The primary fill structure is adjacent to two or more sidewall edges of at least the first IC die and over a third region of the substrate comprising a majority of a space between the first and second IC dies. The primary fill structure is absent from over a second surface, opposite the first surface, of either of the first or second IC dies. The device comprises a secondary fill structure within a first remnant of the space between the primary fill structure and the two or more sidewall edges of the first IC die, and within a second remnant of the space between the primary fill structure and the second IC die.

In seventeenth examples, for any of the sixteenth examples the system comprises a power supply coupled to provide power to the composite IC die package through the host component.

In eighteenth examples, for any of the sixteenth through seventeenth examples the first IC die is a first of a microprocessor core circuitry, wireless radio circuitry, floating point gate array (FPGA) circuitry, power management circuitry, active repeater circuitry, clock generator circuitry, memory circuitry, or input/output buffer circuitry. The second IC die is a second of a microprocessor core circuitry, wireless radio circuitry, floating point gate array (FPGA) circuitry, power management circuitry, active repeater circuitry, clock generator circuitry, memory circuitry, or input/output buffer circuitry.

In nineteenth examples, a method of forming an integrated circuit (IC) device comprises forming a primary fill structure by patterning openings into a fill material layer of a host substrate, bonding first and second IC dies to the host substrate within ones of the openings, and forming a secondary fill structure within remnants of the openings between the primary fill structure and each of the first and second IC dies.

In twentieth examples, for any of the nineteenth examples the method further comprises planarizing the secondary fill structure and the primary fill structure with a surface of at least one of the first or second IC dies.

In twenty-first examples, for any of the nineteenth through twentieth examples patterning the openings comprises forming a first opening through a thickness of the fill material layer, the first opening larger than a footprint of the first IC die, and forming a second opening through a thickness of the fill material layer, the second opening larger than a footprint of the second IC die.

In twenty-second examples, for any of the nineteenth through twenty-first examples bonding the fill material layer to the host substrate further comprises bonding a first surface of the fill material layer to the host substrate and removing a donor substrate to expose a second surface of the fill material layer.

In twenty-third examples, for any of the nineteenth through twenty-second examples forming the secondary fill structure comprises depositing an inorganic dielectric comprising silicon and at least one of oxygen or nitrogen.

In twenty-fourth examples, for any of the nineteenth through twenty-third examples forming the primary fill structure further comprises forming one or more through vias, and bonding the first and second IC dies further comprises forming interdiffused metallurgical bonds between the metallization features of the IC dies and metallization features of the host substrate.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An integrated circuit (IC) device, comprising:
a first IC die comprising a first surface bonded to a first region of a substrate;
a second IC die adjacent to the first IC die and comprising a first surface bonded to a second region of the substrate;
a primary fill structure having an inorganic composition, the primary fill structure occupying a majority of a space between the first and second IC die and adjacent to two or more sidewall edges of at least the first IC die, but not over a second surface, opposite the first surface, of either of the first or second IC dies; and
a secondary fill structure within a first remnant of the space between the primary fill structure and the two or more sidewall edges of the first IC die, and within a second remnant of the space between the primary fill structure and the second IC die.

2. The IC device of claim 1, wherein the secondary fill structure comprises a seam approximately in the middle of each of the first and second remnants of the space.

3. The IC device of claim 1, wherein the secondary fill structure is in contact with a sidewall of the primary fill structure and in contact with a sidewall of each of the first and second IC dies.

4. The IC device of claim 1, wherein:
the primary fill structure has a thickness substantially equal to that of the first IC die and the majority of the space occupied by the primary fill structure is at least 500 μm wide; and
at least one of first or second remnants of the space adjacent to the primary fill structure is less than 40 μm wide.

5. The IC device of claim 4, wherein a width of the first and second remnants of the space are unequal by at least 50% of the smaller of the first or second remnants.

6. The IC device of claim 1, wherein:
the primary fill structure surrounds a perimeter of at least the first IC die;
the secondary fill structure is within a channel surrounding the perimeter of the first IC die; and
the secondary fill structure is substantially co-planar with the first IC die.

7. The IC device of claim 6, wherein:
the primary fill structure surrounds a perimeter of the second IC die;
the secondary fill structure is within a second channel surrounding the perimeter of the second IC die;
the secondary fill structure is substantially co-planar with the second IC die; and
the primary fill structure is contiguous between the first and second channels.

8. The IC device of claim 6, wherein the channel has a different width between the two or more sidewall edges of the first IC die and two or more corresponding sidewall edges of the primary fill structure that face the sidewall edges of the first IC die.

9. The IC device of claim 1, wherein a top surface of the primary fill structure is substantially planar with the second surface of at least one of the first IC die or second IC die.

10. The IC device of claim 9, wherein the top surface of the primary fill structure is substantially planar with a top surface of the secondary fill structure.

11. The IC device of claim 1, wherein the primary fill structure has a significantly higher silicon or metal content than the secondary fill structure.

12. The IC device of claim 11, wherein the primary fill structure comprises predominantly silicon, predominantly silicon and carbon, or predominantly a metal.

13. The IC device of claim 11, wherein the secondary fill structure comprises a greater amount of one or more of a metal, nitrogen, or oxygen than the primary fill structure.

14. The IC device of claim 1, wherein the first and second IC dies are directly bonded to the substrate, and wherein the primary fill structure is directly bonded to the substrate.

15. The IC device of claim 1, further comprising one or more through vias embedded within the primary fill structure and directly bonded to interconnect features of the substrate, and wherein a top surface of the through vias are substantially co-planar with the second surface of the primary fill structure.

16. A system comprising:
a host component; and
a composite integrated circuit (IC) device attached to the host component, the composite IC device comprising:
a host substrate;
a first IC die comprising a first surface bonded to a first region of a substrate;
a second IC die adjacent to the first IC die and comprising a first surface bonded to a second region of the substrate;
a primary fill structure having an inorganic composition, the primary fill structure adjacent to two or more sidewall edges of at least the first IC die and over a third region of the substrate comprising a majority of a space between the first and second IC dies, wherein the primary fill structure is absent from over a second surface, opposite the first surface, of either of the first or second IC dies; and
a secondary fill structure within a first remnant of the space between the primary fill structure and the two or more sidewall edges of the first IC die, and within a second remnant of the space between the primary fill structure and the second IC die.

17. The system of claim 16, further comprising a power supply coupled to provide power to the composite IC die package through the host component.

18. The system of claim 16, wherein:
the first IC die is a first of a microprocessor core circuitry, wireless radio circuitry, floating point gate array (FPGA) circuitry, power management circuitry, active repeater circuitry, clock generator circuitry, memory circuitry, or input/output buffer circuitry; and
the second IC die is a second of a microprocessor core circuitry, wireless radio circuitry, floating point gate array (FPGA) circuitry, power management circuitry, active repeater circuitry, clock generator circuitry, memory circuitry, or input/output buffer circuitry.

19. A method of forming an integrated circuit (IC) device, the method comprising:
forming a primary fill structure by patterning openings into a fill material layer of a host substrate;
bonding first and second IC dies to the host substrate within ones of the openings; and
forming a secondary fill structure within remnants of the openings between the primary fill structure and each of the first and second IC dies.

20. The method of claim 19, further comprising planarizing the secondary fill structure and the primary fill structure with a surface of at least one of the first or second IC dies.

21. The method of claim 19, wherein patterning the openings comprises:
forming a first opening through a thickness of the fill material layer, the first opening larger than a footprint of the first IC die; and
forming a second opening through a thickness of the fill material layer, the second opening larger than a footprint of the second IC die.

22. The method of claim 19, wherein bonding the fill material layer to the host substrate further comprises bonding a first surface of the fill material layer to the host substrate and removing a donor substrate to expose a second surface of the fill material layer.

23. The method of claim 19, wherein forming the secondary fill structure comprises depositing an inorganic dielectric comprising silicon and at least one of oxygen or nitrogen.

24. The method of claim 19, wherein:
forming the primary fill structure further comprises forming one or more through vias; and
bonding the first and second IC dies further comprises forming interdiffused metallurgical bonds between the metallization features of the IC dies and metallization features of the host substrate.
